(19) United States
(12) Patent Application Publication
(10) Pub. No.: US 2002/0092558 A1
(43) Pub. Date: Jul. 18, 2002

(54) Integrated thin film cell and fabrication method thereof

(76) Inventors: Seong Bae Kim, Kwangsan-ku (KR); Kwang Il Chung, Seo-ku (KR); Shin Kook Kim, Mokpo-si (KR); Woo Seong Kim, Buk-ku (KR); Yung Eun Sung, Buk-ku (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 09/910,776

(22) Filed: Jul. 24, 2001

(30) Foreign Application Priority Data
Jan. 18, 2001 (KR) 2001-2949
Apr. 28, 2001 (KR) 2001-23179

(51) Int. Cl. H01L 31/00

(52) U.S. Cl. 136/244; 438/80

(57) ABSTRACT

An integrated thin film battery and fabrication method thereof is provided, in which a plurality of thin film batteries and thin film solar cells are formed in grooves formed on a substrate, to thereby secure stabilities of the thin film batteries and the thin film solar cells and provide a desired charging capacity and output voltage. The integrated thin film battery includes a substrate made of an electrical insulation material and whose one surface is etched to form a groove thereon; and a thin film battery including an anode, an electrolyte, a cathode, and anode and cathode current collectors respectively contacting the anode and cathode, for collecting current, which is formed on a groove formed on the substrate, for charging and discharging electrical energy.

### BACKGROUND OF THE INVENTION

1. Field of the Invention

The present invention relates to an integrated thin film battery and a fabrication method thereof, and more particularly, to an integrated thin film battery and a fabrication method thereof, in which a plurality of thin film batteries and thin film solar cells are formed in grooves formed on a substrate, to thereby secure stabilities of the thin film batteries and the thin film solar cells and provide a desired charging capacity and output voltage.

2. Description of the Related Art

In general, as a semiconductor industry is highly developed, an ultra-compact micro-electric/electronic device turns up in various fields such as a smart card, a MEMS (MicroElectroMechanical System), a MAV (Micro Air Vehicle) and minute medical equipment. Accordingly, a consumption power required by these devices is also minimized and thus the necessity of a thin film battery as a power supply becomes acute.

Most of conventional devices take a pattern where power is received from an external power supply. However, it has become possible to have a power supply in the device by adopting a thin film battery.

Meanwhile, a general structure of a thin film battery has a pattern fabricated by depositing constituent materials on a substrate by use of various semiconductor processes, which includes a feature which can be freely fabricated without substantial restriction of the pattern and magnitude in view of features. A typical structure of such a thin film battery is shown in FIG. 1. Referring to FIG. 1, a unit thin film battery includes a Si substrate 10, an anode current collector 11 formed on the Si substrate 10 and made of a Ti (Pt, Au) family material, an anode 13 formed on the anode current collector 11, and for example, made of LiCoO₂, an electrolyte 14 overlaying the exposed upper surface and side surfaces of the anode 13 and part of the one surface of the Si substrate 10, and for example, made of LiPON, a cathode 15 formed on the electrolyte 14, and for example, made of Li, a cathode current collector 12 overlaying the cathode 15 and the one side surface of the electrolyte 14 and part of the one surface of the Si substrate 10, and made of Cu or Ti family material, in order to block the cathode 15 from reacting upon the atmosphere, and a protective layer 16 for protecting the cathode 15, part of the exposed portion of the electrolyte 14, part of the anode current collector 11, and the cathode current collector 12.

The substrate 10 can be made of glass, alumina, various sapphire semiconductors or polymer, other than Si. The cathode 15 can be formed of SnO₂, SnO, SiTON, Li₄Ti₄O₁₂ other than Li. Also, the anode 13 can be formed of transition metal oxide such as LiNiO₂ and LiMn₂O₄ other than LiCoO₂. The cathode current collector 12 can be made of V, Cr, Mn, Fe, Co, Y, Zr, Hf, Ta other than Cu and Ti.

However, since the above existing unit thin film battery has a pattern deposited on a substrate, the battery is considerably exposed when the battery is formed of a multi-layer. Accordingly, stability of the battery is severely influenced due to the physical action of the exposed portions. Also, the lead wires formed in series or in parallel may be damaged due to the external impact, which lowers lifetime and stability of the battery.

Meanwhile, a thin film solar cell is introduced in order to charge the thin film battery. Accordingly, a thin film battery having a thin film solar cell which can charge and discharge by itself has been developed. A typical example of the thin film battery having the above thin film solar cell is shown in FIG. 2.

Referring to FIG. 2, a conventional thin film battery having a thin film solar cell includes a thin film solar cell 418 formed on an ITO substrate 419 which is a transparent material, and a thin film battery 417 which receives current produced by the thin film solar cell 418 and is charged, of which the detailed structure follows.

The thin film solar cell 418 is formed of an ITO substrate 419, a transparent conductive layer 420 formed on the ITO substrate 419, a p-type semiconductor 421 formed on the transparent conductive layer 420, a semiconductor 422 formed on the p-type semiconductor 421, an n-type semiconductor 423 formed on the semiconductor 422, and a rectification layer 424 formed on the n-type semiconductor 423.

Also, the thin film battery 417 formed on the thin film solar cell 418 is formed of a cathode 425 formed on the rectification layer 424, an electrolyte 426 formed on the cathode 425, an anode 427 formed on the electrolyte 426, an anode current collector 428 formed on the anode 427 and a protective layer 429 formed on the anode current collector 428.

However, in the case of the above conventional thin film battery having a thin film solar cell, an area occupied by the thin film solar cell is restricted by the area of the whole thin film battery, in view of the structure. Thus, an amount of output current of a solar cell is limited in view of the feature of the solar cell in which a capacity is determined in proportional to an area.

### SUMMARY OF THE INVENTION

To solve the above problems, it is an object of the present invention to provide an integrated thin film battery having a desired charging and discharging capacity and an output voltage characteristic in which the thin film batteries are integrated in a stable structure with respect to an external circumstance, and a fabrication method thereof.

It is another object of the present invention to provide an integrated thin film cell having a thin film solar cell and having a stable structure, in which a thin film solar cells are added in the integrated thin film battery to thereby convenience charging and discharging.

To accomplish the above object of the present invention, there is provided an integrated thin film battery comprising: a substrate made of an electrical insulation material and whose one surface is etched to form a groove thereon; and a thin film battery including an anode, an electrolyte, a cathode, and anode and cathode current collectors respectively contacting the anode and cathode, for collecting current, which is formed on a groove formed on the substrate, for charging and discharging electrical energy.

The groove formed on the substrate is formed of a plurality of first grooves separated by insulation walls each made of an electrical insulation material. The anode and cathode current collectors of a plurality of thin film batteries formed on the first groove are independently formed on each first groove. The anode and cathode current collectors further comprises a plurality of connectors each made of a conductor in order to be connected with adjoining anode and cathode current collectors, respectively.

The anode and cathode current collectors are formed commonly contacting anodes and cathodes of a plurality of thin film batteries formed in a plurality of first grooves. The groove formed on the substrate is formed of a plurality of second grooves separated up and down by insulation layers each made of an electrical insulation material. A battery layer by a plurality of thin film batteries formed on one of the plurality of the second grooves and another battery layer by a plurality of thin film batteries formed on another of the plurality of the second grooves are connected to each other either in series or in parallel.

Also, the integrated thin film battery further comprises a thin film solar cell formed on the uppermost layer of the groove formed on the substrate, for converting a solar energy into an electrical energy to be charged into the thin film battery.

There is also provided an integrated thin film battery having a thin film solar cell comprising: a substrate made of an electrical insulation material and whose one surface is etched to form a groove thereon; a thin film battery including an anode, an electrolyte, a cathode, and anode and cathode current collectors respectively contacting the anode and cathode, for collecting current, which is formed on a groove formed on the substrate, for charging and discharging electrical energy; and a thin film solar cell formed on the uppermost layer of the groove formed on the substrate, for converting a solar energy into an electrical energy to be charged into the thin film battery.

There is also provided an integrated thin film battery having a thin film solar cell comprising: a substrate made of an electrical insulation material and whose one surface is etched to form a groove thereon; a thin film battery including an anode, an electrolyte, a cathode, and anode and cathode current collectors respectively contacting the anode and cathode, for collecting current, which is formed on at least one of at least two grooves formed on the substrate, for charging and discharging electrical energy; and a thin film solar cell formed on at least one groove of the grooves adjacent the groove in which the thin film battery is formed, for converting a solar energy into an electrical energy to be charged into the thin film battery.

There is also provided a method for fabricating an integrated thin film battery having an enhanced stability, the integrated thin film battery fabrication method comprising the steps of: (a) etching one surface of a substrate made of an electrical insulation material, to form a first groove capable of accommodating at least one battery layer formed of at least one thin film battery; (b) forming a plurality of battery layers on the first groove, wherein step (b) comprising the sub-steps of (b1) forming a first current collector connecting the first groove to either one electrode of the electrodes of a plurality of unit thin film batteries forming a battery layer, (b2) depositing an insulation material on the first current collector, then etching the deposited result, and forming a plurality of second grooves each accommodating one unit thin film battery on each etched result, (b3) depositing an anode, an electrolyte and a cathode which form a thin film battery on each second groove and forming a plurality of unit thin film batteries, (b4) forming a second current collector on the plurality of unit thin film batteries by deposition, and (b5) forming a plurality of battery layers each obtained by forming an insulation layer made of an insulation material on the second current collector by deposition; (c) forming lead wires for connecting the first and second current collectors of respectively different battery layers among the plurality of battery layers; and (d) forming a protective layer made of an insulation material on the plurality of battery layers.

The first groove is formed in at least depth deeper than a total thickness of the plurality of battery layers formed therein. The second groove is formed in the same depth as a total thickness of the anode, the electrolyte and the cathode forming the unit thin film battery formed therein. The lead wires comprises a first lead wire formed so as to connect each first current collector among the plurality of battery layers, and a second lead wire formed so as to connect each second current collector, in which the lead wires connect the plurality of battery layers in parallel with each other. The lead wire connects the first and second current collectors in respectively adjoining battery layers among the plurality of battery layers, to thereby connect the plurality of battery layers in series with each other. In the case that the anode constituting the unit thin film battery is a transition metal oxide, the battery layer is formed in a single layer. In the case that the anode constituting the unit thin film battery is a vanadium oxide, the battery layer is formed in a multi-layer. The insulation layer and the protective layer are made of insulation materials, which include a buffering function and an electrical insulation characteristic with respect to the volume change upon the charging and discharging of the thin film battery. The protective layer is formed in combination of an electrical insulation material, metal and polymer, to thereby protect the insulation of the thin film battery from an external circumstance. The insulation material is made of one selected from the group consisting of SiO₂, TEOS, SOG, and a combination thereof. Each current collector of the plurality of unit thin film batteries constituting the battery layer is formed as a single current collector with respect to each anode or each cathode, so that the anode and cathode share the current collector in common. Each anode, electrolyte and cathode of the unit thin film battery constituting the battery layer are formed in the same material, time and thickness.

There is also provided a method for fabricating an integrated thin film battery having an enhanced stability, the integrated thin film battery fabrication method comprising the steps of: (a) etching one surface of a substrate made of an electrical insulation material, to form a first groove capable of accommodating a plurality of battery layer formed of a plurality of thin film batteries; (b) forming a first current collector connecting the first groove to either one electrode of the electrodes of a plurality of unit thin film batteries forming a battery layer; (c) depositing an insulation material on the first current collector, then etching the deposited result, and forming a plurality of second grooves each accommodating one unit thin film battery on each etched result; (d) depositing an anode, an electrolyte and a cathode which form a thin film battery on each second groove and forming a plurality of unit thin film batteries, to thereby form the plurality of unit thin film battery; (e) forming a second current collector on the plurality of unit thin film batteries by deposition, and (f) forming a protective layer made of an insulation material on the second current collector.

There is also provided a method for fabricating an integrated thin film battery having a thin film solar cell, the integrated thin film battery fabrication method comprising the steps of: (a) etching one surface of a substrate made of an electrical insulation material, to form at least one groove; (b) forming a thin film battery on at least one groove among the at least one groove and connecting the formed thin film batteries with each other; and (c) forming a thin film solar cell on at least one groove among other grooves adjacent the thin film battery formed in step (b), to then connect the thin film battery and the thin film solar cell.

The at least one thin film battery formed in step (b) is connected either in series or in parallel. The groove formed on the substrate is separately formed by an electrical insulation material.

There is also provided a method for fabricating an integrated thin film battery having a thin film solar cell, the integrated thin film battery fabrication method comprising the steps of: (a) etching one surface of a substrate, to form a first groove accommodating a thin film solar cell; (b) forming at least one second groove having a depth capable of accommodating at least one thin film battery; (c) forming a thin film battery on the at least one second groove, and connecting the formed thin film batteries; and (d) forming a thin film solar cell on the thin film battery formed in step (c).

The second groove formed in step (b) is separately formed by an electrical insulation material. The at least one thin film battery formed in step (c) is connected either in series or in parallel.

As described above, the present invention introduces a plurality of grooves on a substrate made of a semiconductor substrate, in which a thin film battery integrated in the horizontal direction and in the vertical direction is formed to thereby secure an excellent stability in comparison with the existing thin film battery, and the anode and cathode current collectors are shared in common to thereby accomplish a simplification in process. Also, the integrated thin film battery according to the present invention is excellent in view of the stability in comparison with the existing integrated thin film battery. In the present invention, it is also possible to fabricate a thin film battery having a low cost, high capacity and high energy density. Further, in the case that a thin film solar cell is formed in a thin film battery, the thin film solar cell enables self-charging to thereby heighten convenience in use.

### BRIEF DESCRIPTION OF THE DRAWINGS

The above objects and other advantages of the present invention will become more apparent by describing the preferred embodiments thereof in more detail with reference to the accompanying drawings in which:

FIG. 1 is a cross-sectional view for explaining structure of a conventional thin film battery;

FIG. 2 is a cross-sectional view for explaining structure of a thin film battery having a conventional thin film solar cell;

FIG. 3 is a cross-sectional view for explaining structure of an integrated thin film battery according to a first embodiment of the present invention;

FIGS. 4A to 4M are cross-sectional views for explaining a fabrication process of an integrated thin film battery according to the first embodiment of the present invention;

FIG. 5 is a cross-sectional view for explaining structure of an integrated thin film battery according to a second embodiment of the present invention;

FIG. 6 is a cross-sectional view for explaining structure of an integrated thin film battery according to a third embodiment of the present invention;

FIGS. 7A to 7E are cross-sectional views for explaining a fabrication process of an integrated thin film battery according to the third embodiment of the present invention; and

FIG. 8 is a cross-sectional view for explaining structure of an integrated thin film battery having a thin film solar cell according to a fourth embodiment of the present invention.

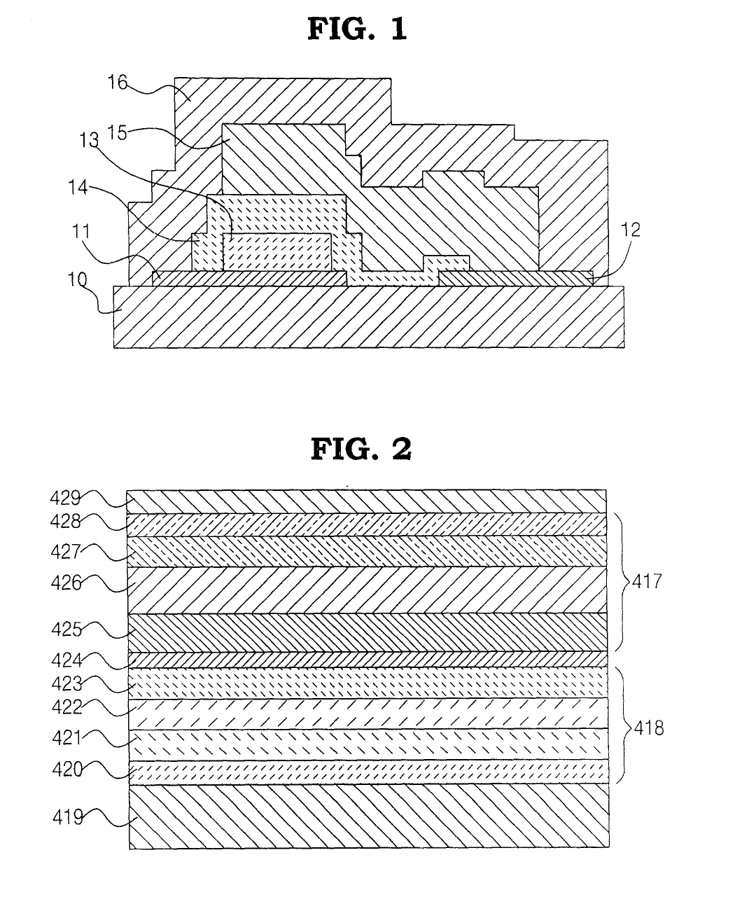

### DETAILED DESCRIPTION OF THE INVENTION

Preferred embodiments of the present invention will be described with reference to the accompanying drawings.

In the present invention, grooves capable of accommodating a plurality of thin film batteries are formed on a substrate made of an electrical insulation material, for example, a silicon oxide substrate, and battery layers formed of the a plurality of thin film batteries are formed on the grooves in a single layer or multi-layer, to thereby facilitate setting of the charging and discharging capacity and output voltage of the battery.

Also, a thin film solar cell for charging the thin film battery is formed to thereby enable self-charging.

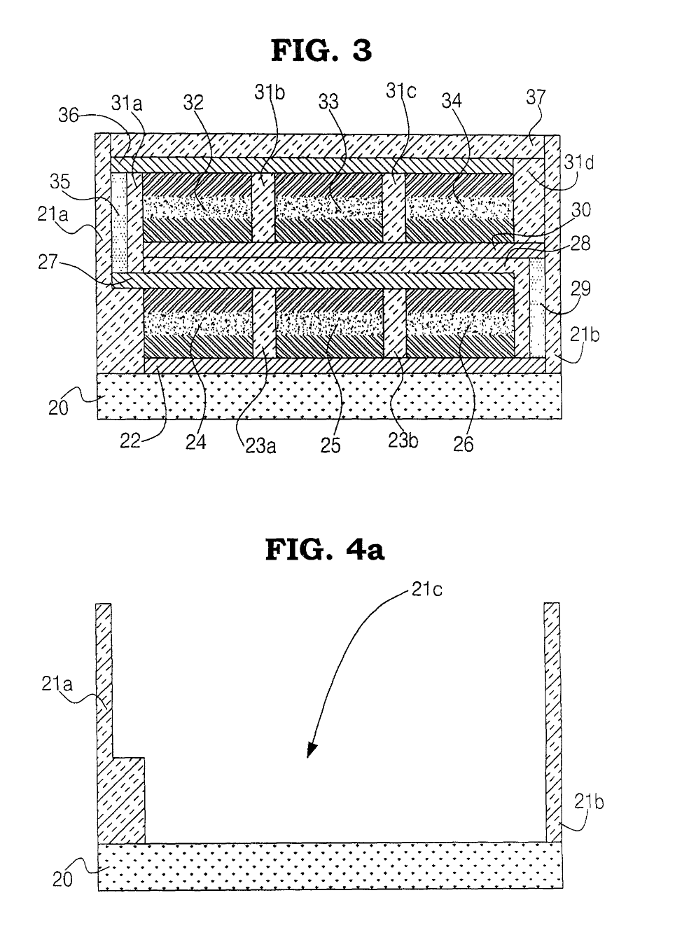

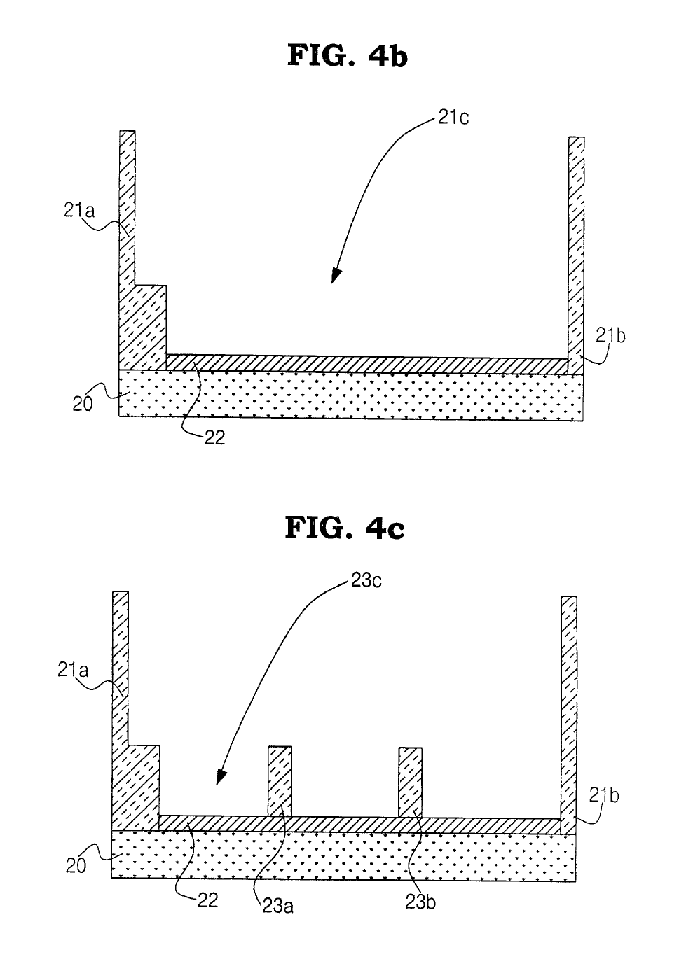

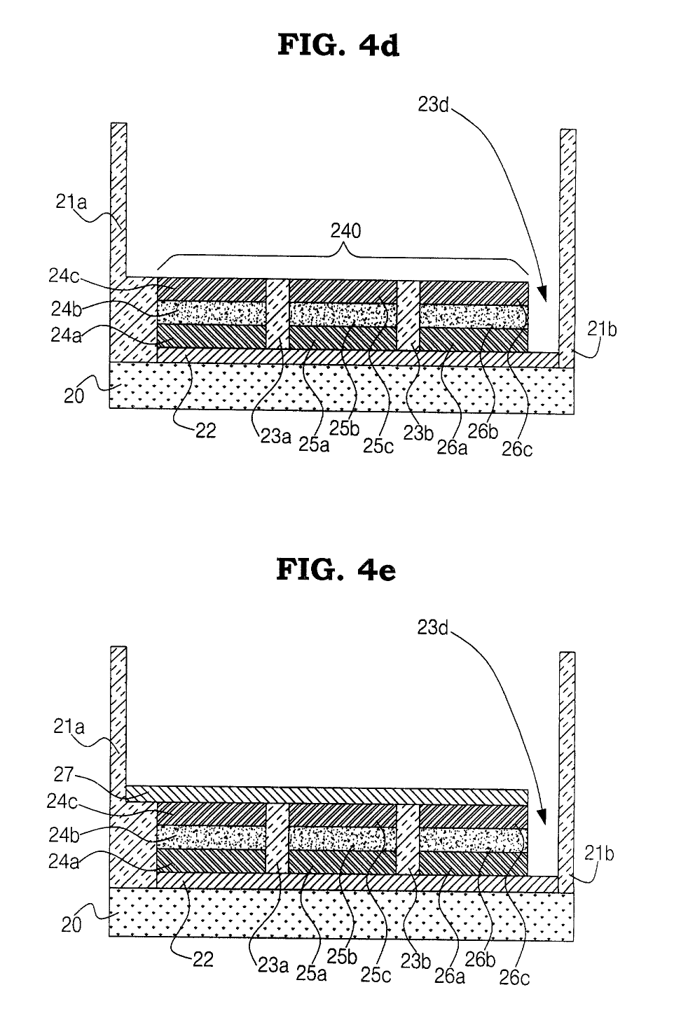

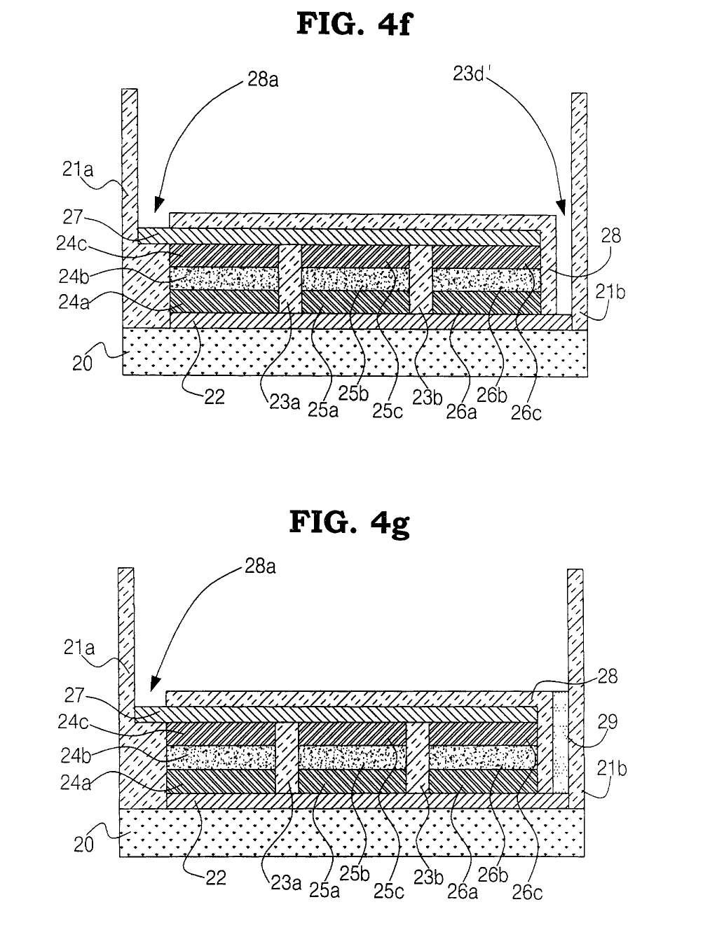

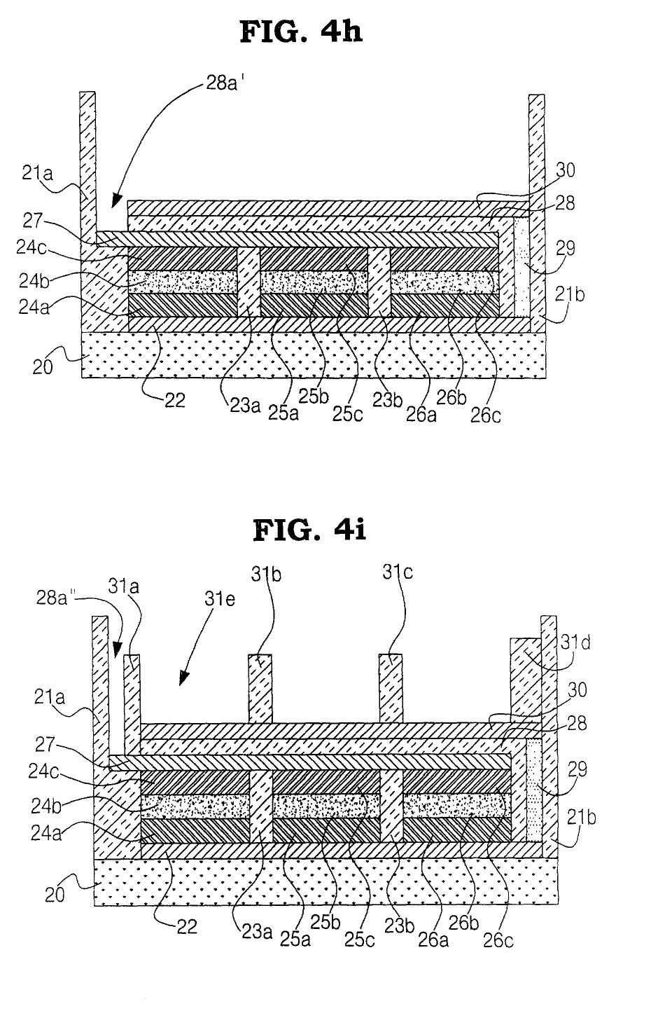

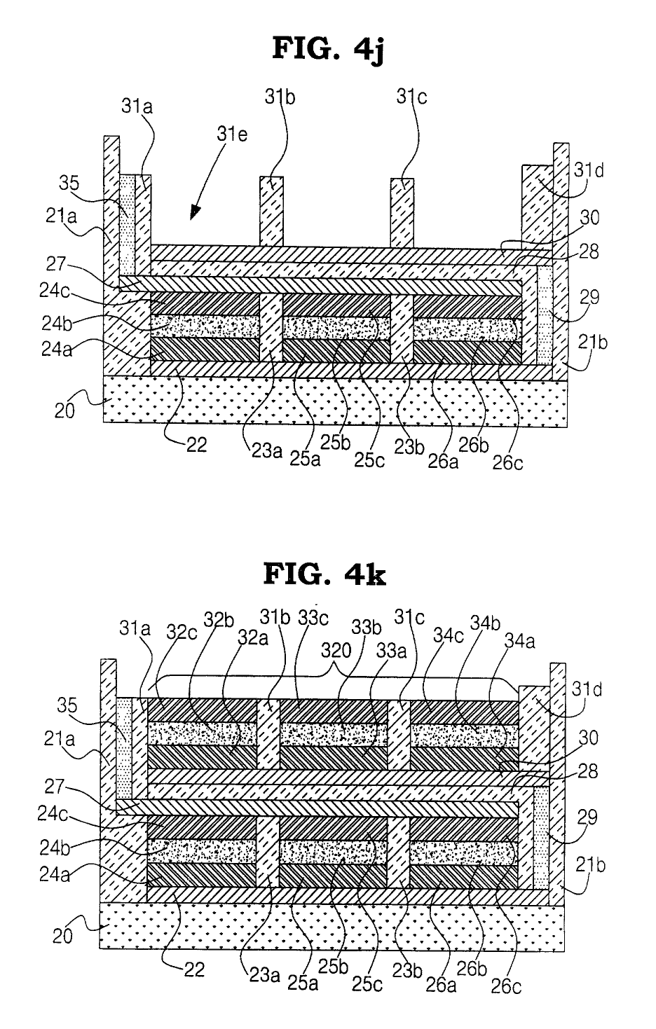

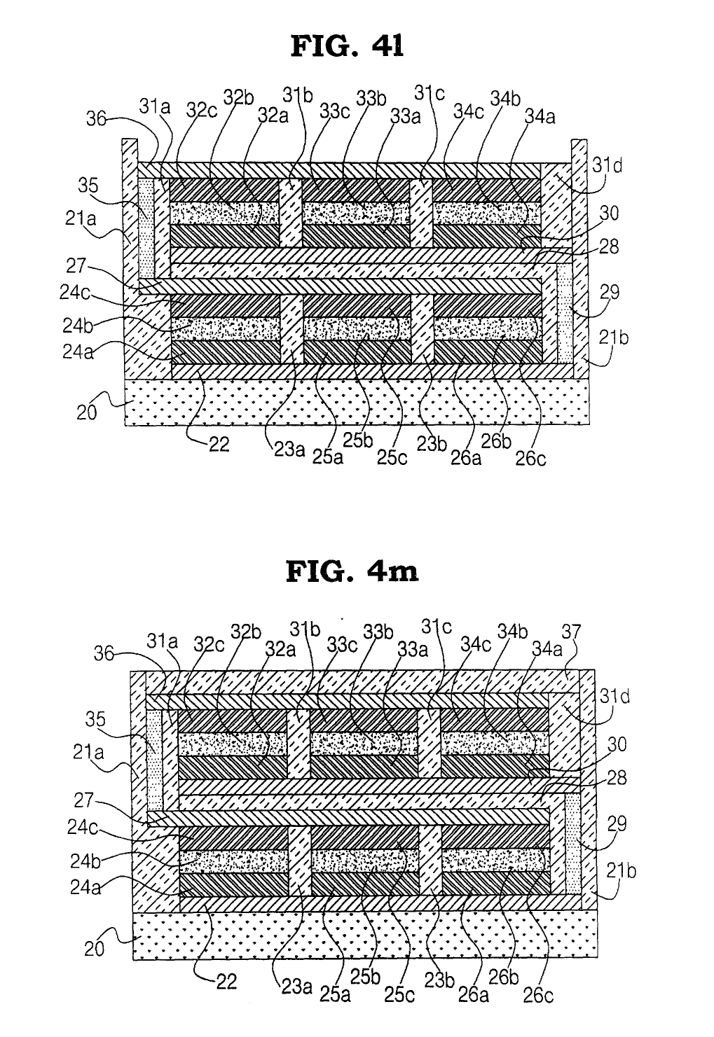

1. First Embodiment of FIGS. 3 and 4A-4M

In the present invention, a plurality of unit thin film batteries 24-26 or 32-34 are integrated to thereby fabricate an integrated thin film battery. As shown in FIG. 3, considering voltage and current to be output, a plurality of unit thin film batteries 24-26 or 32-34 are formed in a single layer, to thereby form a single battery layer. The battery layers are formed in a multi-layer up and down.

As described above, the battery layers formed of the unit thin film batteries 24-26 and 32-34 are formed as a multi-layer. The battery layers are connected in series or in parallel with each other, to thereby set and output a desired output voltage and current amount.

Here, the present invention does not form a single unit thin film battery which has the most current capacity per volume of a battery, but causes the volume of the battery due to a volume occupied by insulators which section the plurality of unit thin film batteries 24-26 and 32-34 to be reduced, when a battery is formed. The reason follows.

In the case of a thin film battery, the output voltage per a unit thin film battery is determined as about 2.5-4V (the output voltage is 2.5V in the case of vanadium oxide, and 3.7V in the case of transition metal oxide). Thus, in the case that a driving voltage of an electric/electronic device driven by a battery is higher than an output voltage of 3-4V of a unit thin film battery, a separate unit for adjusting a voltage is required. In this case, since current flows out from a single battery, a charging and discharging efficiency according to a number of times of charging and discharging is lowered.

The present invention connects a plurality of unit thin film batteries in series or in parallel in order to solve the problem of the above-described existing unit thin film battery, to thereby set a desired output voltage and current amount at the fabrication stage of an integrated thin film battery and fabricate the integrated thin film battery. As a result, a method of constituting a thin film battery with several unit thin film batteries enables a higher efficient discharging than that of a single unit thin film battery.

The present invention provides two kinds of embodiments in which a plurality of unit thin film batteries are connected in series or in parallel. The first embodiment shown in FIG. 3 where a plurality of unit thin film batteries are connected in parallel will be described in detail below with reference to FIGS. 4A-4M.

An integrated thin film battery according to the first embodiment of the present invention includes a first battery layer 240 constituted by first through third unit thin film batteries 24˜25, a second battery layer 320 constituted by fourth through sixth unit thin film batteries 32˜34, a substrate 20 and first outer wall 21a and 21b surrounding the lower surface and side surfaces of the first battery layer 240 and the side surfaces of the second battery layer 320, first and second anode and cathode current collectors 22, 27, 30 and 36 formed on the respective upper and lower surfaces of the first and second battery layers 240 and 320, for collecting the respective current, a first lead wire 29 connecting the first anode current collector 22 and the second anode current collector 30 with each other, a second lead wire 35 connecting the first cathode current collector 27 and the second cathode current collector 36 with each other, an insulation layer 28 for electrically insulating the first battery layer 240 and the second battery layer 320, and a protective layer 37 for sealing the first and second battery layers 240 and 320 together with the upper portions of the first outer walls 21a and 21b.

The first and second battery layers 240 and 320 include first inner walls 23a and 23b for electrically insulating and sectioning the first through third unit thin film batteries 24-26 and second inner walls 31b and 31c for electrically insulating and sectioning the fourth through sixth unit thin film batteries 32-34, respectively.

In the case of the substrate 20 made of an insulation material used for a thin film battery, that is, silicon oxide, the area of the substrate 20 is determined considering a capacity of a battery. An insulation material such as alumina or polymer other than silicon oxide is used as the substrate. Also, the thickness of the substrate 20 is determined considering the thickness of the first and second battery layers 240 ad 320 which are accommodated in the substrate 20.

A fabrication process of the first embodiment will be described below with reference to FIGS. 4A-4M.

As shown in FIG. 4A, the remaining portion other than the first outer walls 21a and 21b formed on the outer boundary portions of one surface of the substrate 20 is etched and removed in order to form a first groove 21c which provides a space accommodating the first and second battery layers 240 and 320 respectively constituted by the first through sixth unit thin film batteries 24˜25 and 32˜34, on the substrate 20.

The first outer walls 21a and 21b formed by etching are edge walls formed in the edge portion on the upper surface of the substrate 20. The depth of the first groove 21c formed by the first outer walls 21a and 21b is formed considering the thickness of the first and second battery layers 240 and 320 accommodated in the groove 21c as described above.

Here, as an etching processing method, a physical etching method using plasma or ion or a chemical etching method using an acid material or a liquid chemical material is used in the case of silicon oxide and alumina, while a photo-lithography method using a photo sensitive material is used in the case of polymer.

As shown in FIG. 4B, a first anode current collector 22 is deposited so that it occupies the whole bottom area of the first groove 21c formed in the above-described method. The first anode current collector 22 plays a role of connecting the anodes of the first through third unit thin film batteries 24-26 formed thereon in parallel with each other, in which an available material is Pt, Ti, V or Al. Also, in order to facilitate contact to the substrate 20, an additional metal layer of Ti and so on (for example, in the case that the anode of the battery is LiCoO₂, the material is Ti+Pt, while in the case of VO₂, the material is V or Al) can be introduced.

As a deposition method which is used for depositing the first anode current collector 22, are there a DC magnetron sputtering, a RF magnetron sputtering, and a thermal evaporation.

In order to form the first through third unit thin film batteries 24-26 after forming the first anode current collector 22 as described above, the first groove 21c should be separated into a number of second grooves 23c. In order to form a number of second grooves 23c, an insulation material such as silicon oxide is deposited on the anode current collector 22 in the same manner as that of forming the first groove 21 and then etched, to thereby form first inner walls 23a and 23b protrudingly, as shown in FIG. 4C.

On the second grooves 23c formed by the first inner walls 23a and 23b and the first outer walls 21a and 21b are deposited in turn constituents forming first through third unit thin film batteries 24-26, that is, anodes 24a, 25a and 26a, electrolytes 24b, 25b and 26b, cathodes 24c, 25c and 26c, as shown in FIG. 4D. Here, the anodes 24a, 25a and 26a, the electrolytes 24b, 25b and 26b, the cathodes 24c, 25c and 26c which constitute first through third unit thin film batteries 24-26 are preferably deposited in the same material, time and thickness. By doing so, a productiveness is enhanced and a battery reversal problem can be solved. Also, when a battery is used after integration, a deterioration of the individual unit thin film battery due to the capacity difference of the first through sixth unit thin film batteries 24-26 and 32˜34 can be prevented.

The respective anodes 24a, 25a, 26a, 32a, 33a and 34a constituting the first through sixth unit thin film batteries 24-26 and 32-34 are made of a transition metal oxide such as LiCoO₂, LiNiO₂, LiMn₂O₄, and LiVO₂ and a mixture thereof. The electrolytes 24b, 25b, 26b, 32b, 33b and 34b is made of a nitride such as Li₃PO₄, that is, LiₓPO_{y}N_{z}, the cathodes 24c, 25c, 26c, 32c, 33c, and 34c are made of Li, Sn, SnO and SnO₂.

The anodes 24a, 25a, 26a, 32a, 33a and 34a is deposited by a RF magnetron sputtering, the electrolytes 24b, 25b, 26b, 32b, 33b and 34b is deposited by a reactive RF magnetron sputtering, the cathodes 24c, 25c, 26c, 32c, 33c and 34c is deposited by a thermal evaporation in case of Li, and is deposited by a RF magnetron sputtering in case of Sn.

Here, when the first through third unit thin film batteries 24-26 is formed, a first space 23d for accommodating an insulation layer 28 and a lead wire 29 which will be described later remains between the one side of the first battery layer 240 and the first outer wall 21b.

A first cathode current collector 27 is deposited on the first battery layer 240 as shown in FIG. 4E. The first cathode current collector 27 plays a role of connecting the cathodes of the first through third unit thin film batteries 24-26 in parallel, and deposited by DC or RF magnetron sputtering or a thermal evaporation using Cu, Co or Ti.

An insulation material such as silicon oxide or alumina is deposited on the remaining portion excluding part of the first cathode current collector 28 and the side wall of the first battery layer 240 which contacts the first space 23d, to form the insulation layer 28, as shown in FIG. 4F. Here, the first space 23d is occupied by the insulation layer 28 and the remaining space is used as a first lead wire accommodation space 23d′ where the first lead wire 29 is formed, which will be described later.

Also, a small space is formed between the first outer wall 21a and the other end of the insulation layer 28, and is used as a second space 28a for accommodating a second wall 31a and a second lead wire 35 which will be described later.

The first through third unit thin film batteries 24-26, and the fourth through sixth unit thin film batteries 32-34 which are disposed on the substrate 20 in the horizontal direction, the first and second inner walls 23a, 23b, 31b and 31c formed between the first and second battery layers 240 and 320 which are disposed in the vertical direction, the insulation layer 28 and the second outer walls 31a and 31d should play a role of electrically insulating the first through sixth unit thin film batteries 24-26 and 32˜34, and also secure a mechanical stability. Also, a buffering function with respect to the volume change according to the charging and discharging of the thin film battery should be achieved. A material which satisfies the above features is selected from the group consisting of SiO₂, TEOS and SOG and a combination thereof.

A first lead wire 29 is formed as shown in FIG. 4G by depositing a material such as Au, Al, Cu, Co and Ti on a first lead wire accommodation space 23d′ for accommodating the first lead wire 29 among the lead wires necessary for combination of batteries such as serial connection and parallel connection between the first battery layer 240 formed in the second groove 23c and the second battery layer 320 to be described later. Thus, one end of the first anode current collector 22 and the lower end of the first lead wire 29 is electrically connected with each other.

Then, in order to form a second battery layer 320, a second anode current collector 30 is formed on the first battery layer 240 in the same manner as that of forming the first anode current collector 22, as shown in FIG. 4H. Here, one end of the second anode current collector 30 is connected to the upper end of the first lead wire 29, and the other end of the second anode current collector 30 is formed so as to be coincided with the end of the insulation layer 28 to thus form an extended second space 28a′ maintaining a second space 28a.

A third groove 31e accommodating the fourth through sixth unit thin film batteries 32-34 constituting the second battery layer 320 is formed in the same manner as that of forming the first groove 23c, as shown in FIG. 4I.

In other words, an insulation material such as silicon oxide or alumina is deposited on the second anode current collector 30, and etched again, to thereby form second outer walls 31a and 31d inscribed in the first outer walls 21a and 21b, and second outer walls 31b and 31c formed between the second outer walls 31a and 31d, simultaneously. Accordingly, a third groove 31e produced by the second outer walls 31a and 31d and the second inner walls 31b and 31c is formed.

Here, the extended second space 28′ is occupied by the second outer wall 31a in part, and the remaining portion is used as a second lead wire accommodation space 28″ which can accommodate a second lead wire 35. The second lead wire 35 is formed in the second lead wire accommodation space 28a″ in the same manner as that of forming the first lead wire 29, as shown in FIG. 4J.

The fourth through sixth unit thin film batteries 32-34 constituting the second battery layer 320 are formed on the third groove 31e in the same manner as that of forming the first battery layer 240, as shown in FIG. 4K.

A second cathode current collector 36 is formed on the second lead wire 35 and the second battery layer 320 in the same manner as that of forming the fist cathode current collector 27, as shown in FIG. 4L. Here, the second cathode current collector 36 connects each cathode 32c, 33c and 34c of the fourth through sixth unit thin film batteries 24-26 and 32-34 constituting the second battery layer 320 with the upper end of the second lead wire 35.

An insulation material such as silicon oxide or alumina is deposited on the second cathode current collector 36, to thereby deposit a protective layer 37 for electrically insulating the second battery layer and protecting the battery, as shown in FIG. 4M. Here, the protective layer 37 should possess a function of protecting the battery from the external circumstance together with the electric insulation function with respect to the uppermost second cathode current collector 36. Accordingly, metal or polymer such as silicon oxide and alumina is used to thereby secure a mechanical stability.

The thin film battery formed in the process as described above has a battery structure where the first battery layer 240 in which the first through third unit thin film batteries 24-26 are connected in parallel with each other and the second battery layer 320 in which the fourth through sixth unit thin film batteries 32-34 are connected in parallel with each other, are connected in parallel with each other.

Thus, each of the first and second battery layers 240 and 320 can output a three-times current capacity in comparison with the unit thin film battery. Also, since the first and second battery layers 240 and 320 are connected in parallel with each other, a six-times current capacity can be output.

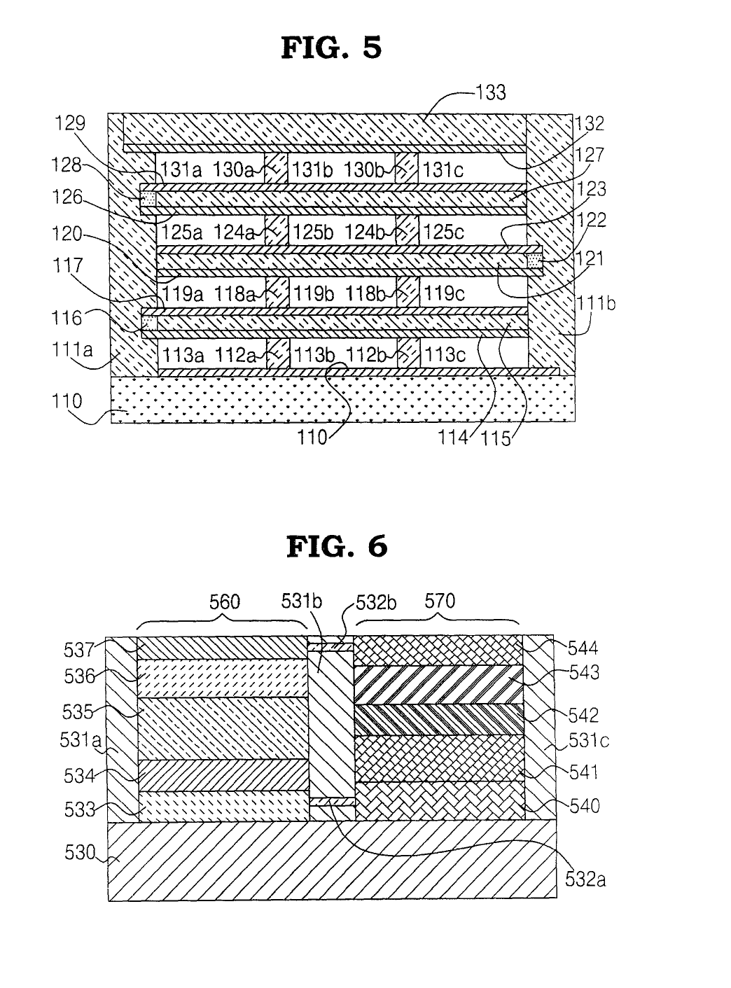

2. Second Embodiment In FIG. 5, a battery layer constituted by three unit thin film batteries is deposited four times. In this case, each battery layer is connected in series with each other. Accordingly, a three-times current capacity and a four-times voltage increase effect are provided.

In the second embodiment shown in FIG. 5, outer walls 110a and 110b are formed on a substrate 109, in the same method as that of forming the first outer walls 21a and 21b of the first embodiment, a first anode current collector 111 is formed, first inner walls 112a and 112b are formed, first thin film batteries 113a-113c are formed on a groove formed by the first inner walls 112a and 112b, and a first cathode current collector 114 is formed, to thereby form a first battery layer.

A first insulation layer 115 is formed on the first battery layer, a first lead wire 116 is formed to the left side of the first insulation layer 115, and then a second anode current collector 117, second inner walls 118a and 118b, second thin film batteries 119a-119c, and a second cathode current collector 120 are formed in turn, to thereby form a second battery layer.

A second insulation layer 121 is formed on the second battery layer, a second lead wire 122 is formed to the right side of the second insulation layer 121, and then a third anode current collector 123, third inner walls 124a and 124b, third thin film batteries 125a-125c, and a third cathode current collector 126 are formed in turn, to thereby form a third battery layer.

Also, a third insulation layer 127 is formed on the third battery layer, a third lead wire 128 is formed to the left of the third insulation layer 127, and then a fourth anode current collector 129, fourth inner walls 130a and 130b, fourth thin film batteries 131a-131c, and a fourth cathode current collector 132 are formed in turn, to thereby form a fourth battery layer and finally form a protective layer 133.

Thus, each of the first through battery layers are connected in series with each other, a three-times current capacity and a four-times voltage can be output.

Meanwhile, the first and second embodiments have been described with respect to the cases that three unit thin film batteries are connected in series or in parallel, respectively. However, the combination thereof can vary according to a necessary voltage and current capacity. Also, as illustrated in the first and second embodiments, the present invention can collect current from a unit thin film battery constituting a single-layer thin film battery by a single anode/cathode current collector, to thereby output the collected current. Therefore, the present invention has a process simplification characteristic that a current collector need not be separately formed with respect to each unit thin film battery.

The first and second embodiments have been described with respect to the cases that a transition metal oxide is used as an anode material constituting a thin film battery. However, in order to use a positive active material after having deposited the transition metal oxide, a thermal treatment is necessarily required. However, it is not possible to perform a repeated thermal treatment when a thin film cell is deposited in a multi-layer.

The thermal treatment of the anode material is accomplished at 800° C. or so. Although a single-layer thin film battery is formed at the same time, the electrolytes and lithium cathodes on the lower battery layer are influenced when the subsequently formed battery layer is thermally treated. As a result, the solid electrolyte and the lithium cathodes are all degenerated, to thereby cause a problem capable of not playing a role of a battery.

Thus, in the case that a multi-layer thin film battery is formed as in the present invention, a material which can be used as an anode material is limited to vanadium oxide (VO₂) which does not require a thermal treatment.

As a result, in the case that a thin film battery is constituted into a multi-layer, vanadium oxide is used as an anode material of the thin film battery. In the case that a thin film battery is constituted into a single layer, an anode is firstly deposited and then an electrolyte and a cathode are deposited. Thus, an integrated thin film battery can be constituted by using transition metal oxide.

3. Third Embodiment

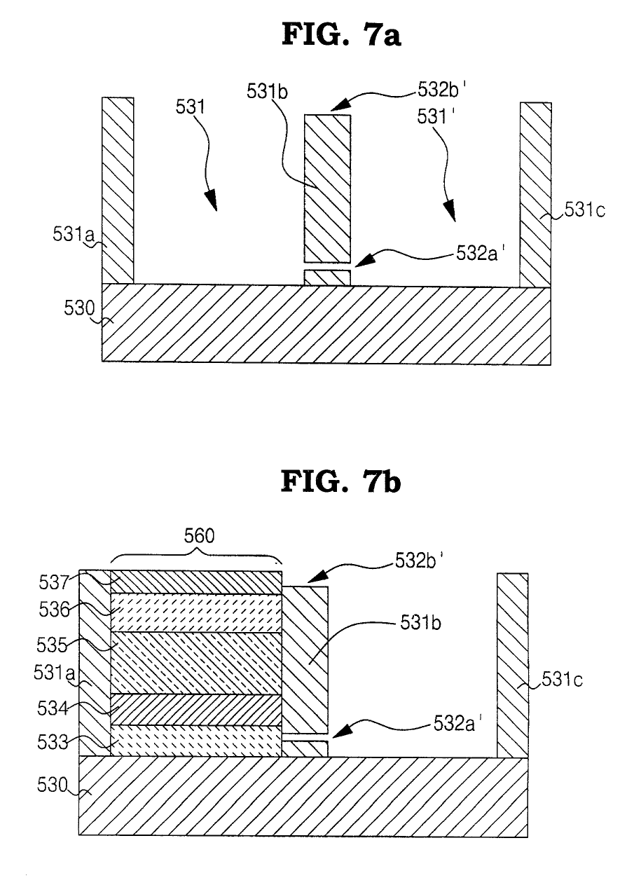

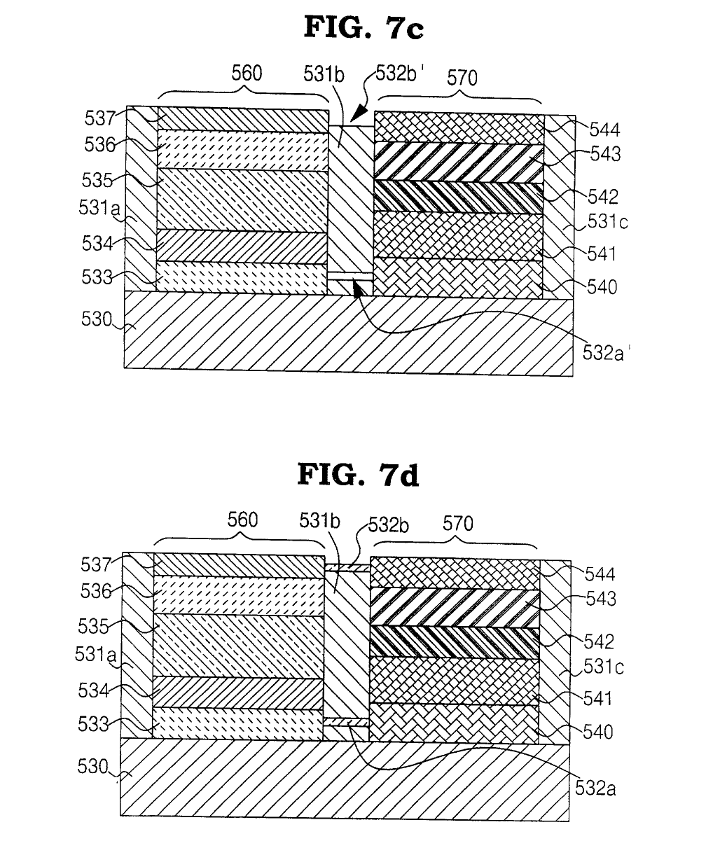

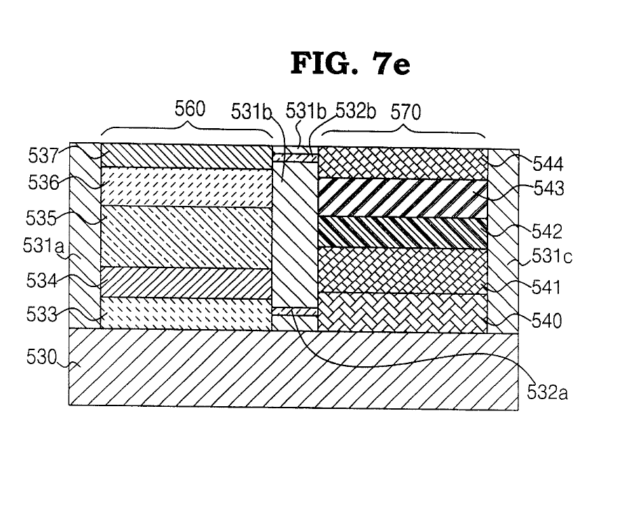

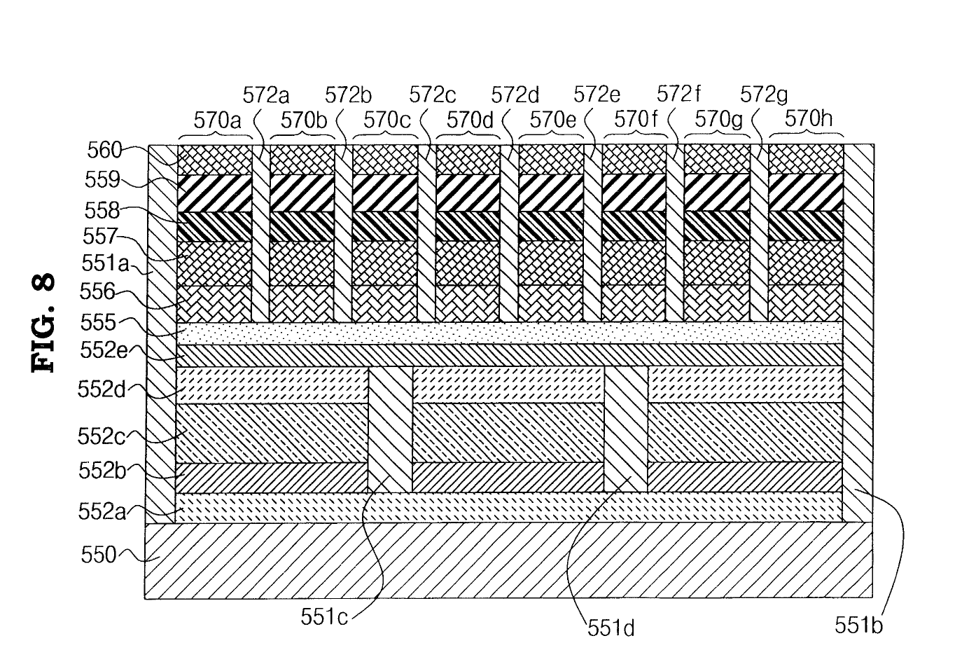

In a third embodiment of the present invention, a fabrication method of forming a thin film solar cell and a thin film battery, by using two grooves, respectively, will be described below with reference to FIGS. 6 and 7A-7E.

A substrate 30 is formed to have a thickness of several hundred micrometers or so, is made of a silicon material. On the substrate 30 is formed an insulation material, for example, silicon oxide SiO₂. With an etching method as shown in FIG. 7A, a number of grooves 531 and 531′ each having a depth of several tens through several hundreds micrometers are formed. Thus, first through third walls 531a, 531b and 531c forming each groove 531 or 531′ are formed.

As described above, a thin film battery 560 and a thin film solar cell 570 are respectively formed on first and second grooves 531 and 531′ which are adjacent to each other among a number of formed grooves 531 and 531′.

The thin film battery 560 is formed in the first groove 531. In the case of the thin film battery 560 as shown in FIG. 7B, an anode current collector 533, an anode 534, an electrolyte 535, a cathode 536, and a cathode current collector 537 in the case of the thin film battery 560 are formed in sequence from the substrate 530, according to a general thin film battery fabrication process.

Also, the thin film solar cell 570 is formed in the second groove 531′. In the case of the thin film solar cell 570 as shown in FIG. 7C, a transparent conductive layer 540, a p-type semiconductor 541, an intrinsic (i-type) semiconductor 542, an n-type semiconductor 543 and a rectification layer 544 are formed in sequence from the substrate 530, according to a general thin film solar cell fabrication process.

Meanwhile, a first lead wire 530a which connects the anode current collector 533 of the thin film battery 560 and the transparent conductive layer 540 with each other, and a second lead wire 532b which connects the cathode current collector 537 and the rectification layer 544 are formed on a second wall 531b separating the first groove 531 and the second groove 531′ from each other, of which process will follow.

As shown in FIG. 7A, when the first and second grooves 531 and 531′ are formed, the portion where a first lead wire accommodation portion 532a′ accommodating a first lead wire 532a which is formed on the lower end of the second wall 531b is etched.

Then, the first lead wire 532a is formed, and a second wall portion is formed up to the positions where the first lead wire 532a and a second lead wire accommodation portion 532b′ are formed. Then, as shown in FIG. 7D. a second lead wire 532b is formed again, and then as shown in FIG. 7E, the remaining portion of a second wall 531b is formed.

Also, an overcharging preventive circuit (not shown) for preventing that power produced by the thin film solar cell 570 is overcharged into the thin film battery is added, to thereby complete an integrated thin film battery.

The third embodiment constituted by the above process and structure forms at least one pair of the thin film battery 560 and the thin film solar cell 570 which are formed in a number of paired grooves on the substrate 530, that is, the first and second grooves 531 and 531′, respectively, to thereby enable power generation and charging.

That is, the number of capacity of the thin film battery and the thin film solar cell are set and formed, according to a required voltage and current capacity of an electronic device using the thin film battery having the thin film solar cell according to the present invention.

In particular, if a voltage condition varies according to a kind of a battery formed in a groove, one or more solar cell is formed in order to satisfy a charging condition of a battery to thereby supply a charging power source.

4. Fourth Embodiment

In the fourth embodiment of the present invention as shown in FIG. 8, after forming three grooves formed by four walls accommodating a number of thin film batteries 552a-552e (in this embodiment, three thin film batteries are used) on a substrate 550, that is, a first wall 551a, a second wall 551b, and a third wall 551c and a fourth wall 551d formed between the first wall 551a and the second wall 551b, anode current collectors 552a, anodes 552b, electrolytes 552c, cathodes 552d, and cathode current collectors 552e are formed in sequence, in order to form three thin film batteries.

The anode current collectors 552a and the cathode current collectors 552e are connected in common to the anodes 552b and the cathodes 552d, respectively as illustrated in the first and second embodiments, to thereby play a role of collecting current.

Then, a buffering layer 555 is firstly formed in order to form a thin film solar cell in the two-stage grooves formed on the thin film batteries 552a-552e and formed on the first and second walls 551a and 551b.

Then, since the thin film solar cell has an output voltage of about 0.5V per battery, a voltage of 3.0 through 4.0V should be able to be output in order to charge a thin film battery.

As shown in FIG. 8, in order to form eight grooves on the buffering layer 555, fifth through eleventh walls 572a-572g are formed using an insulation material. A transparent conductive layer 556, a p-type semiconductor 557, an intrinsic (i-type) semiconductor 558, an n-type semiconductor 559 and a rectification layer 560 are formed in sequence at the same time from the substrate 550, in the grooves formed by the fifth through eleventh walls 572a-572g, to thereby complete first through eighth thin film solar cells 570a-570h.

Also, as in the third embodiment, an overcharging preventive circuit (not shown) for preventing that the power produced by the first through eighth thin film solar cells 570a-570h is overcharged in the three thin film batteries 552a-552e is installed to thereby complete an integrated thin film battery.

Also, the fourth embodiment has been described with respect to the case that eight thin film solar cells are used to charge three thin film batteries which are connected in parallel. However, as being the case, the number of the thin film solar cells and the number of the thin film batteries can be adjusted into various kinds of combination, that is, the voltage adjustment is adjusted by the number of batteries which are connected in series and the current amount adjustment is adjusted by changing the number of the cells which are connected in parallel, to thereby adjust the charging voltage by the thin film solar cells and the output voltage of the thin film cells.

As described above, the present invention introduces a number of grooves on a substrate made of a semiconductor substrate, to thereby form integrated thin film batteries in the horizontal and vertical directions, respectively. Accordingly, the present invention can secure an excellent stability in comparison to the existing thin film battery, and share anode and cathode current collectors in common, to thereby achieve a simplification in process. In the present invention, it is also possible to fabricate a thin film battery having a low cost, high capacity and high energy density, as well as a more excellent stability than that of the existing integrated thin film battery.

Also, since the thin film solar cell is formed in the thin film battery, the present invention enables a self-charging by the thin film solar cell to thereby heighten a convenience in use.

As described above, the present invention has been described with respect to the particularly preferred embodiments. However, the present invention is not limited in the above-described embodiments. It is apparent to one who is skilled in the art that there are many variations and modifications, within the technical scope of the appended claims without departing off the spirit of the present invention.

What is claimed is:

1. An integrated thin film battery comprising:
a substrate made of an electrical insulation material and whose one surface is etched to form a groove thereon; and
a plurality of thin film batteries each including an anode, an electrolyte, a cathode, and anode and cathode current collectors respectively contacting the anode and cathode, for collecting current, which is formed on a groove formed on the substrate, for charging and discharging electrical energy.

2. The integrated thin film battery of claim 1, wherein the groove formed on the substrate is formed of a plurality of first grooves separated by insulation walls each made of an electrical insulation material.

3. The integrated thin film battery of claim 2, wherein the anode and cathode current collectors of a plurality of thin film batteries formed on the first groove are independently formed on each first groove.

4. The integrated thin film battery of claim 3, wherein the anode and cathode current collectors further comprises a plurality of connectors each made of a conductor in order to be connected with adjoining anode and cathode current collectors, respectively.

5. The integrated thin film battery of claim 2, wherein the anode and cathode current collectors are formed commonly contacting anodes and cathodes of a plurality of thin film batteries formed in a plurality of first grooves.

6. The integrated thin film battery of claim 1, wherein the groove formed on the substrate is formed of a plurality of second grooves separated up and down by insulation layers each made of an electrical insulation material.

7. The integrated thin film battery of claim 6, wherein a battery layer by a plurality of thin film batteries formed on one of the plurality of the second grooves and another battery layer by a plurality of thin film batteries formed on another of the plurality of the second grooves are connected to each other either in series or in parallel.

8. The integrated thin film battery of one of claims 1 to 7, further comprising a thin film solar cell formed on the uppermost layer of the groove formed on the substrate, for converting a solar energy into an electrical energy to be charged into the thin film battery.

9. An integrated thin film battery having a thin film solar cell comprising:
a substrate made of an electrical insulation material and whose one surface is etched to form a groove thereon;
a plurality of thin film batteries each including an anode, an electrolyte, a cathode, and anode and cathode current collectors respectively contacting the anode and cathode, for collecting current, which is formed on a groove formed on the substrate, for charging and discharging electrical energy; and
a plurality of thin film solar cells each formed on the uppermost layer of the groove formed on the substrate, for converting a solar energy into an electrical energy to be charged into the thin film battery.

10. An integrated thin film battery having a thin film solar cell comprising:
a substrate made of an electrical insulation material and whose one surface is etched to form a groove thereon;
a thin film battery including an anode, an electrolyte, a cathode, and anode and cathode current collectors respectively contacting the anode and cathode, for collecting current, which is formed on at least one of at least two grooves formed on the substrate, for charging and discharging electrical energy; and
a thin film solar cell formed on at least one groove of the grooves adjacent the groove in which the thin film battery is formed, for converting a solar energy into an electrical energy to be charged into the thin film battery.

11. A method for fabricating an integrated thin film battery having an enhanced stability, the integrated thin film battery fabrication method comprising the steps of:
(a) etching one surface of a substrate made of an electrical insulation material, to form a first groove capable of accommodating at least one battery layer formed of at least one thin film battery;
(b) forming a plurality of battery layers on the first groove, wherein step (b) comprising the sub-steps of
(b1) forming a first current collector connecting the first groove to either one electrode of the electrodes of a plurality of unit thin film batteries forming a battery layer,
(b2) depositing an insulation material on the first current collector, then etching the deposited result, and forming a plurality of second grooves each accommodating one unit thin film battery on each etched result,
(b3) depositing an anode, an electrolyte and a cathode which form a thin film battery on each second groove and forming a plurality of unit thin film batteries,
(b4) forming a second current collector on the plurality of unit thin film batteries by deposition, and
(b5) forming a plurality of battery layers each obtained by forming an insulation layer made of an insulation material on the second current collector by deposition;
(c) forming lead wires for connecting the first and second current collectors of respectively different battery layers among the plurality of battery layers; and
(d) forming a protective layer made of an insulation material on the plurality of battery layers.

12. The integrated thin film battery fabrication method of claim 11, wherein the first groove is formed in at least depth deeper than a total thickness of the plurality of battery layers formed therein.

13. The integrated thin film battery fabrication method of claim 11, wherein the second groove is formed in the same depth as a total thickness of the anode, the electrolyte and the cathode forming the unit thin film battery formed therein.

14. The integrated thin film battery fabrication method of claim 11, wherein the lead wires comprises a first lead wire formed so as to connect each first current collector among the plurality of battery layers, and a second lead wire formed so as to connect each second current collector, in which the lead wires connect the plurality of battery layers in parallel with each other.

15. The integrated thin film battery fabrication method of claim 11, wherein the lead wire connects the first and second current collectors in respectively adjoining battery layers among the plurality of battery layers, to thereby connect the plurality of battery layers in series with each other.

16. The integrated thin film battery fabrication method of claim 11, wherein in the case that the anode constituting the unit thin film battery is a transition metal oxide, the battery layer is formed in a single layer.

17. The integrated thin film battery fabrication method of claim 11, wherein in the case that the anode constituting the unit thin film battery is a vanadium oxide, the battery layer is formed in a multi-layer.

18. The integrated thin film battery fabrication method of claim 11, wherein the insulation layer and the protective layer are made of insulation materials, which include a buffering function and an electrical insulation characteristic with respect to the volume change upon the charging and discharging of the thin film battery.

19. The integrated thin film battery fabrication method of claim 11 or 18, wherein the protective layer is formed in combination of an electrical insulation material, metal and polymer, to thereby protect the insulation of the thin film battery from an external circumstance.

20. The integrated thin film battery fabrication method of claim 18, wherein the insulation material is made of one selected from the group consisting of SiO₂, TEOS, SOG, and a combination thereof.

21. The integrated thin film battery fabrication method of claim 11, wherein each current collector of the plurality of unit thin film batteries constituting the battery layer is formed as a single current collector with respect to each anode or each cathode, so that the anode and cathode share the current collector in common.

22. The integrated thin film battery fabrication method of claim 11, wherein each anode, electrolyte and cathode of the unit thin film battery constituting the battery layer are formed in the same material, time and thickness.

23. A method for fabricating an integrated thin film battery having an enhanced stability, the integrated thin film battery fabrication method comprising the steps of:
(a) etching one surface of a substrate made of an electrical insulation material, to form a first groove capable of accommodating a plurality of battery layer formed of a plurality of thin film batteries;
(b) forming a first current collector connecting the first groove to either one electrode of the electrodes of a plurality of unit thin film batteries forming a battery layer;
(c) depositing an insulation material on the first current collector, then etching the deposited result, and forming a plurality of second grooves each accommodating one unit thin film battery on each etched result;
(d) depositing an anode, an electrolyte and a cathode which form a thin film battery on each second groove and forming a plurality of unit thin film batteries, to thereby form the plurality of unit thin film battery;
(e) forming a second current collector on the plurality of unit thin film batteries by deposition, and
(f) forming a protective layer made of an insulation material on the second current collector.

24. A method for fabricating an integrated thin film battery having a thin film solar cell, the integrated thin film battery fabrication method comprising the steps of:
(a) etching one surface of a substrate made of an electrical insulation material, to format least one groove;
(b) forming a thin film battery on at least one groove among the at least one groove and connecting the formed thin film batteries with each other; and
(c) forming a thin film solar cell on at least one groove among other grooves adjacent the thin film battery formed in step (b), to then connect the thin film battery and the thin film solar cell.

25. The integrated thin film battery fabrication method of claim 24, wherein the at least one thin film battery formed in step (b) is connected either in series or in parallel.

26. The integrated thin film battery fabrication method of claim 24, wherein the groove formed on the substrate is separately formed by an electrical insulation material.

27. A method for fabricating an integrated thin film battery having a thin film solar cell, the integrated thin film battery fabrication method comprising the steps of:
(a) etching one surface of a substrate, to form a first groove accommodating a thin film solar cell;
(b) forming at least one second groove having a depth capable of accommodating at least one thin film battery;
(c) forming a thin film battery on the at least one second groove, and connecting the formed thin film batteries; and
(d) forming a thin film solar cell on the thin film battery formed in step (c).

28. The integrated thin film battery fabrication method of claim 27, wherein the second groove formed in step (b) is separately formed by an electrical insulation material.

29. The integrated thin film battery fabrication method of claim 27, wherein the at least one thin film battery formed in step (c) is connected either in series or in parallel.
